(19) United States
(12) Patent Application Publication
(10) Pub. No.: US 2005/0274610 A1
(43) Pub. Date: Dec. 15, 2005

(54) MAGNETRON SPUTTERING APPARATUS

(75) Inventor: Takayuki Iseki, Yokohama-shi (JP)

Correspondence Address: CONNOLLY BOVE LODGE & HUTZ LLP, SUITE 800, 1990 M STREET NW, WASHINGTON, DC, 20036-3425, US

(73) Assignee: VICTOR COMPANY OF JAPAN, LIMITED, Kanagawa-ku (JP)

(21) Appl. No.: 10/908,723

(22) Filed: May 24, 2005

(30) Foreign Application Priority Data
May 25, 2004 (JP) 2004-154485
Jun. 21, 2004 (JP) 2004-182724

(51) Int. Cl. C23C 14/32

(52) U.S. Cl. 204/298.2; 204/298.19; 204/192.12

(57) ABSTRACT

A magnetron sputtering apparatus is composed of a vacuum chamber (10), a target (15), a substrate (13), an anode (14) for supporting the substrate (13) that is disposed in the vacuum chamber, a cathodic body (16) for supporting the target (15) that is allocated so as to confront with the anode (14) and a magnetic field generating section (50) for generating a magnetic field on a surface of the target (15) that is allocated in neighborhood of one side of the cathodic body (16) opposite to the target (15). The target (15) is in a shape of square flat plate. The magnetic field generating section (50) is further composed of a yoke (51) in flat plate corresponding to the target (15), a first permanent magnet (52) in rectangular parallelepiped that is disposed in the middle of the yoke (51) and second and third permanent magnets (53, 54) in rectangular parallelepiped that are disposed in both end portions of the yoke (51) respectively. The magnetron sputtering apparatus is further composed of a driving unit (56) for swinging the magnetic field generating section (50) within a prescribed angle with centering a line as an axis of rotation, wherein the line passes through an approximate center (56) of the yoke (51) and is perpendicular to magnetic flux lines of the magnetic field and in parallel with the target (15).

### BACKGROUND OF THE INVENTION

1. Field of the Invention

The present invention relates to a magnetron sputtering apparatus, particularly, relates to a magnetron sputtering apparatus, which enables to expand an erosion area while maintaining higher sputtering efficiency and further enables to improve usable efficiency of target.

2. Description of the Related Arts

A sputtering apparatus has been utilized for forming various kinds of thin films such as conductive films, dielectric films and semiconductive films. A magnetron sputtering apparatus in particular enables to ensure a higher film forming speed by capturing high density plasma in an area neighboring a target.

Further, a magnetron sputtering apparatus enables to generate stable plasma in a pressure range of a high vacuum. The plasma is low in impurity.

Accordingly, a magnetron sputtering apparatus has been established as the mainstream of sputtering apparatuses in the field of forming a thin film.

FIG. 31 is a conceptional cross sectional view of a first conventional magnetron sputtering apparatus according to the prior art in common.

FIG. 32 shows a cross sectional view of an erosion portion formed on a target when being sputtered by the first conventional magnetron sputtering apparatus shown in FIG. 31.

FIG. 33 is a conceptional cross sectional view of a second conventional magnetron sputtering apparatus according to the second prior art.

FIG. 34 shows a cross sectional view of an erosion portion formed on a target when being sputtered by the second conventional magnetron sputtering apparatus shown in FIG. 33.

FIG. 35 is a conceptional cross sectional view of a third conventional magnetron sputtering apparatus according to the third prior art.

FIG. 36 shows a cross sectional view of an erosion portion formed on a target when being sputtered by the third conventional magnetron sputtering apparatus shown in FIG. 35.

In FIG. 31, the first conventional magnetron sputtering apparatus is composed of a vacuum chamber 10, a substrate 13, an anode 14, a target 15, a cathodic body 16 and a magnetic field generating section 20. The vacuum chamber 10 is provided with an exhaust opening 11, which is connected to a not shown vacuum pump, and a gas intake duct 12 for introducing inert gas through a flow control valve 12a.

Inside the vacuum chamber 10, the anode 14 is disposed as a substrate holder to hold the substrate 13 of which surface is formed with a thin film, and the cathodic body 16 on which the target 15 is securely placed is disposed so as to confront with the anode 14.

Further, a high frequency power supply 19 is connected to the cathodic body 16 through an impedance matching device 18, wherein the high frequency power supply 19 and the vacuum chamber 10 is grounded respectively.

The cathodic body 16 is further composed of a cylinder section 16a and a target supporting section 16b and disposed inside a cathode shielding section 10a, which constitutes the vacuum chamber 10, through an insulative member 17.

Further, the cathodic body 16 makes the target 15 expose to an open area of the cathode shielding section 10a in the vacuum chamber 10.

Furthermore, the magnetic field generating section 20 is provided at a position close to the target 15 inside the cathodic body 16 and generates magnetic field on a surface of the target 15.

In this particular case, the target 15 is a square flat plate, so that the magnetic field generating section 20 is composed of a yoke 21 in flat plate corresponding to the target 15 and three permanent magnets 22, 23 and 24 in rectangular parallelepiped. The permanent magnets 22, 23 and 24 are fixed on the yoke 21 in parallel with each other. The permanent magnet 22 disposed in the middle of the yoke 21 is magnetized such that a top end surface toward the target supporting section 16b is the N-pole. In case of the permanent magnets 23 and 24 disposed on the both ends of the yoke 21, each top end surface of them toward the target supporting section 16b is magnetized in the S-pole.

Operations of the first conventional magnetron sputtering apparatus are described next.

When electric power is supplied from the high frequency power supply 19 to the cathodic body 16, discharge occurs between the target supporting section 16b, which functions as a cathode, and the anode 14, and resulting in generating plasma in the vacuum chamber 10. Positive ions of the plasma hit impulsively the target 15 on the surface and make atoms of the target 15 scatter inside the vacuum chamber 10. The scattered atoms are deposited on the surface of the substrate 13 as a thin film. In this case, the plasma is converged in a magnetic field, that is, a magnetron area, which is constituted by the magnetic field generating section 20 in a neighborhood of the surface of the target 15. A sputtering efficiency enables to be improved by higher plasma density caused by the converged plasma, and resulting in accelerating film forming speed.

In the above-mentioned first conventional magnetron sputtering apparatus, the magnetic field that confines plasma is statically formed on a part of the surface of the target 15, so that erosion is consequentially concentrated on the part.

As shown in FIG. 32, deeply eroded portions 25 and 26 are generated only in a partial region on the target 15 in which erosion is concentrated, and the target 15 is obliged to be replaced although almost all regions of the target 15 other than the eroded portions 25 and 26 are still kept in sufficient thickness. Consequently, usable efficiency of the target 15 is deteriorated.

Various ideas for improving the above-mentioned problem of concentration of erosion have been proposed. Following ideas, for example, have been proposed.

(1) The Japanese publication of unexamined utility model applications No. 05-20303/1993 teaches that sputtering efficiency is improved by constituting a strong toroidal magnetic field on the surface of a target by means of a magnetic circuit in specific configuration.

(2) The Japanese publication of unexamined patent applications No. 05-179441/1993 teaches that rotating a magnetic field generating section 30 shown in FIG. 33 with respect to a center axis of a target 15A makes an erosion area uniform. In FIG. 33, the magnetic field generating section 30 is constituted smaller in size than that of the target 15A in case the target 15A is in disciform. The magnetic field generating section 30 is mounted on a rotating platform 31 and rotated with respect to a center axis of the target 15A while the magnetic field generating section 30 is maintained in parallel with the target 15A inside the cathodic body 16.

(3) The Japanese publication of unexamined patent applications No. 2002-69637 discloses a magnetic field generating section 40 shown in FIG. 35. In FIG. 35, the magnetic field generating section 40 is supported by a rod 45 that is fixed to under a yoke 41 and enables to be moved vertically by the rod 45. A permanent magnet 42 disposed in the middle of the yoke 41 is magnetized much stronger than a ring permanent magnet 43, which is disposed in an outer circumferential area of the yoke 41 with surrounding the permanent magnet 42, so that magnetic flux lines are shifted to the outer circumferential area of the magnetic field generating section 40.

According to the Japanese publication of unexamined patent applications No. 2002-69637, as shown in FIG. 35, the magnetic flux lines are configured so as to be extended outward. Consequently, a region on the target 15A in which plasma is converged most moves outward in proportion to increases in distance between the magnetic field generating section 40 and the target 15A.

Accordingly, moving the magnetic field generating section 40 vertically makes a plasma converged area move in the radial direction, and resulting in enabling to expand an erosion area extremely.

According to a magnetron sputtering apparatus that is proposed by the Japanese publication of unexamined utility model applications No. 05-20303/1993, the magnetic circuit for generating a strong toroidal magnetic field is complicated in constitution.

Further, a configuration of a magnetic field is basically identical to that shown in FIG. 31. Consequently, erosion is locally concentrated on the surface of the target similar to the partial concentration of erosion shown in FIG. 32.

Accordingly, the magnetron sputtering apparatus proposed by the Japanese publication of unexamined utility model applications No. 05-20303/1993 is not effective to improve usable efficiency of target.

According to the second conventional magnetron sputtering apparatus shown in FIG. 33 that is proposed by the Japanese publication of unexamined patent applications No. 05-179441/1993, the magnetic field generating section 30 is miniaturized in comparison with the magnetic field generating section 20 shown in FIG. 31. By rotating the magnetic field generating section 30 in the circumferential direction of the target 15A, as shown in FIG. 34, an erosion area is expanded, particularly, in a center portion 35 and a circumferential portion 36 in comparison with the erosion area shown in FIG. 32. Consequently, usable efficiency of target is improved in some degree. However, an erosion amount at a middle portion 37 between the center portion 35 and the circumferential portion 36 is small.

Accordingly, the second conventional magnetron sputtering apparatus shown in FIG. 33 just enables to improve sputtering efficiency by the order of 50% at most in comparison with the sputtering efficiency of the target 15 shown in FIG. 32 sputtered by the first conventional magnetron sputtering apparatus shown in FIG. 31.

According to the third conventional magnetron sputtering apparatus shown in FIG. 35 that is proposed by the Japanese publication of unexamined patent applications No. 2002-69637, there exists more magnetic flux lines, which are made to be in parallel with the surface of the target 15A. The magnetic flux lines make a plasma converged area move in the radial direction, so that, as shown in FIG. 36, a major area of the target 15A except for a middle portion 45 is improved in erosion, particularly, a circumferential area 46 is more eroded in comparison with the erosion condition of the target 15 shown in FIG. 32. Consequently, sputtering efficiency enables to be improved more. However, an erosion condition of the middle portion 45 is almost the same as that shown in FIG. 32.

Accordingly, the third conventional magnetron sputtering apparatus shown in FIG. 35 is not effective to improve usable efficiency of target.

### SUMMARY OF THE INVENTION

Accordingly, in consideration of the above-mentioned problems of the prior arts, an object of the present invention is to provide a magnetron sputtering apparatus, which enables to uniform erosion of a target as flat as possible while higher sputtering efficiency is realized. The magnetron sputtering apparatus enables to improve usable efficiency of target as well as sputtering efficiency.

In order to achieve the above object, the present invention provides, according to an aspect thereof, a magnetron sputtering apparatus comprising: a vacuum chamber; a target; a substrate; an anode for supporting the substrate disposed in the vacuum chamber; a cathodic body for supporting the target allocated so as to confront with the anode; and a magnetic field generating section for generating a magnetic field on a surface of the target, being allocated in neighborhood of one side of the cathodic body opposite to the target, wherein the target is in a shape of square flat plate, and wherein the magnetic field generating section is further composed of a yoke in flat plate corresponding to the target, a first permanent magnet in rectangular parallelepiped being disposed in the middle of the yoke and second and third permanent magnets in rectangular parallelepiped being disposed in both end portions of the yoke respectively, the magnetron sputtering apparatus further comprising a driving means for swinging the magnetic field generating section within a prescribed angle with centering a line as an axis of rotation, wherein the line passes through an approximate center of the yoke and is perpendicular to magnetic flux lines of the magnetic field and in parallel with the target.

According to another aspect of the present invention, there provided a magnetron sputtering apparatus comprising: a vacuum chamber; a target; a substrate; an anode for supporting the substrate disposed in the vacuum chamber; a cathodic body for supporting the target allocated so as to confront with the anode; and a magnetic field generating section for generating a magnetic field on a surface of the target, being allocated in neighborhood of one side of the cathodic body opposite to the target, wherein the target is in a shape of circular flat plate, and wherein the magnetic field generating section is further composed of a yoke in circular flat plate having a smaller diameter than the target, a first permanent magnet being disposed in a middle of the yoke and a second permanent magnet in annular shape being disposed in a circumferential area of the target, and wherein the first and second permanent magnets of the magnetic field generating section are designated such that a product of a mean value of magnetic field strength at and an area of a top end surface of the first permanent magnet is larger that another product of a mean value of magnetic field strength at and an area of a top end surface of the second permanent magnet, the magnetron sputtering apparatus further comprising a rotational driving means for revolving the magnetic field generating section in orbital motion with maintaining a distance from the target constant while rotating the magnetic field generating section.

According to a further aspect of the present invention, there provided a magnetron sputtering apparatus comprising: a vacuum chamber; a target; a substrate; an anode for supporting the substrate disposed in the vacuum chamber; a cathodic body for supporting the target allocated so as to confront with the anode; and a magnetic field generating section for generating a magnetic field on a surface of the target, being allocated in neighborhood of one side of the cathodic body opposite to the target, wherein the magnetic field generating section is further composed of a yoke in flat plate corresponding to the target, a first permanent magnet being disposed in the middle of the yoke, a second permanent magnet in annular shape having the same magnetic polarity being disposed in an outer circumferential area of the yoke and a third permanent magnet in annular shape having an inverse magnetic polarity to the first and second permanent magnets being disposed between the first and second permanent magnets, and wherein the first and second permanent magnets of the magnetic field generating section are designated such that a product of a mean value of magnetic field strength at and an area of a top end surface of the third permanent magnet is larger that another product of a mean value of each magnetic field strength at and a sum of each area of top end surfaces of the first and second permanent magnet.

According to a furthermore aspect of the present invention, there provided a magnetron sputtering apparatus comprising: a vacuum chamber; a target; a substrate; an anode for supporting the substrate disposed in the vacuum chamber; a cathodic body for supporting the target allocated so as to confront with the anode; and a magnetic field generating section for generating a magnetic field on a surface of the target, being allocated in neighborhood of one side of the cathodic body opposite to the target, wherein the magnetic field generating section is further composed of a yoke in flat plate corresponding to the target, a first permanent magnet being disposed in the middle of the yoke and a second permanent magnet having an inverse magnetic polarity to the first permanent magnet and magnetic field strength weaker than the first permanent magnet being disposed in an end portion of the yoke with surrounding the first permanent magnet, the magnetron sputtering apparatus further comprising a motion controller unit for moving the magnetic field generating section horizontally and vertically within reach of the magnetic field generated between the first and second permanent magnets to the target.

According to a more aspect of the present invention, there provided a magnetron sputtering apparatus comprising: a vacuum chamber; a target; a substrate; an anode for supporting the substrate disposed in the vacuum chamber; a cathodic body for supporting the target allocated so as to confront with the anode; and a magnetic field generating section for generating a magnetic field on a surface of the target, being allocated in neighborhood of one side of the cathodic body opposite to the target, wherein the magnetic field generating section is further composed of a yoke in flat plate corresponding to the target, a first permanent magnet being disposed in the middle of the yoke and a second permanent magnet having an inverse magnetic polarity to the first permanent magnet and magnetic field strength weaker than the first permanent magnet being disposed in an end portion of the yoke with surrounding the first permanent magnet, the magnetron sputtering apparatus further comprising a slanting motion controller unit for swinging the magnetic field generating section within a prescribed angle while pivoting an approximate center of the magnetic field generating section within reach of the magnetic field generated between the first and second permanent magnets to the target.

Other object and further features of the present invention will be apparent from the following detailed description when read in conjunction with the accompanying drawings.

### BRIEF DESCRIPTION OF THE DRAWINGS

FIG. 1 is a cross sectional view of a magnetron sputtering apparatus according to a first embodiment of the present invention.

FIGS. 2(a) to 2(c) are pattern diagrams showing a relationship between a magnetic field (magnetic flux lines) and a target when swinging a magnetic field generating section of the magnetron sputtering apparatus according to the first embodiment of the present invention.

FIG. 2(d) is a plan view of the magnetic field generating section shown in FIGS. 1 and 2(a) to 2(c).

FIG. 3 shows a cross sectional view of an erosion portion formed on a target when being sputtered by the magnetron sputtering apparatus according to the first embodiment of the present invention.

FIGS. 4(a) to 4(c) are pattern diagrams showing a relationship between a magnetic field (magnetic flux lines) and a target when swinging a magnetic field generating section of the magnetron sputtering apparatus according to the second embodiment of the present invention.

FIG. 5 shows a cross sectional view of an erosion portion formed on a target when being sputtered by the magnetron sputtering apparatus according to the second embodiment of the present invention.

FIG. 6 is a cross sectional view of a magnetron sputtering apparatus according to a third embodiment of the present invention.

FIG. 7 is a plan view of a supporting mechanism and a rotation and revolution mechanism of a magnetic field generating section in the magnetron sputtering apparatus shown in FIG. 6.

FIG. 8 shows a cross sectional view of an erosion portion formed on a target when being sputtered by the magnetron sputtering apparatus according to the third embodiment of the present invention.

FIG. 9 is a cross sectional view of a magnetron sputtering apparatus according to a fourth embodiment of the present invention.

FIG. 10 is a cross sectional view of a magnetron sputtering apparatus according to a fifth embodiment of the present invention.

FIG. 11 is a cross sectional view of a magnetron sputtering apparatus according to a sixth embodiment of the present invention.

FIG. 12 is a cross sectional view of a magnetron sputtering apparatus according to a seventh embodiment of the present invention.

FIG. 13 (a) is a plan view of a magnetic field generating section of the magnetron sputtering apparatus shown in FIG. 12 corresponding to a target in square shape.

FIG. 13(b) is a plan view of another magnetic field generating section of the magnetron sputtering apparatus shown in FIG. 12 corresponding to a target in disciform.

FIG. 14 shows a cross sectional view of an erosion portion formed on a target when being sputtered by the magnetron sputtering apparatus according to the seventh embodiment of the present invention.

FIG. 15 shows another cross sectional view of an erosion portion formed on the target when being sputtered by the magnetron sputtering apparatus according to the seventh embodiment of the present invention in case a magnetic field between permanent magnets of the magnetic field generating section is not disproportionated.

FIG. 16 is a cross sectional view of a magnetron sputtering apparatus according to an eighth embodiment of the present invention.

FIGS. 17(a) and 17(b) are pattern diagrams showing a relationship between a magnetic field (magnetic flux lines) and a target when a magnetic field generating section of the magnetron sputtering apparatus shown in FIG. 16 is moved vertically.

FIG. 18 shows a cross sectional view of an erosion portion formed on a target when being sputtered by the magnetron sputtering apparatus shown in FIG. 16.

FIG. 19 is a cross sectional view of a magnetron sputtering apparatus according to a ninth embodiment of the present invention.

FIG. 20 is a pattern diagram showing a relationship between a magnetic field (magnetic flux lines) and a target when a magnetic field generating section of the magnetron sputtering apparatus shown in FIG. 19 is moved horizontally while the magnetic field generating section is disposed in close proximity to the target.

FIG. 21 shows a cross sectional view of an erosion portion formed on the target when the magnetic field generating section is moved horizontally as shown in FIG. 20 while the magnetic field generating section is disposed in close proximity to the target.

FIG. 22 is a pattern diagram showing a relationship between a magnetic field (magnetic flux lines) and the target when the magnetic field generating section of the magnetron sputtering apparatus shown in FIG. 19 is moved horizontally while the magnetic field generating section is disposed apart from the target.

FIG. 23 shows a cross sectional view of an erosion portion formed on the target when the magnetic field generating section is moved horizontally as shown in FIG. 22 while the magnetic field generating section is disposed apart from the target.

FIG. 24 shows a cross sectional view of an erosion portion formed on the target when the magnetic field generating section is moved vertically and horizontally as shown in FIGS. 20 and 22 with respect to the target.

FIG. 25 is a cross sectional view of a magnetron sputtering apparatus according to a tenth embodiment of the present invention.

FIG. 26 is a pattern diagram showing a relationship between a magnetic field (magnetic flux lines) and a target when a magnetic field generating section of the magnetron sputtering apparatus shown in FIG. 25 is moved horizontally while the magnetic field generating section is slanted to the left by a prescribed angle.

FIG. 27 shows a cross sectional view of an erosion portion formed on the target when the magnetic field generating section is moved horizontally while the magnetic field generating section is slanted as shown in FIG. 26.

FIG. 28 is a pattern diagram showing a relationship between a magnetic field (magnetic flux lines) and a target when the magnetic field generating section of the magnetron sputtering apparatus shown in FIG. 25 is moved horizontally while the magnetic field generating section is slanted to the right by a prescribed angle.

FIG. 29 shows a cross sectional view of an erosion portion formed on the target when the magnetic field generating section is moved horizontally while the magnetic field generating section is slanted as shown in FIG. 28.

FIG. 30 shows a cross sectional view of an erosion portion formed on the target when the magnetic field generating section is moved horizontally while the magnetic field generating section is slanted to the left or the right as shown in FIGS. 26 and 28.

FIG. 31 is a conceptional cross sectional view of a first conventional magnetron sputtering apparatus according to the prior art in common.

FIG. 32 shows a cross sectional view of an erosion portion formed on a target when being sputtered by the first conventional magnetron sputtering apparatus shown in FIG. 31.

FIG. 33 is a conceptional cross sectional view of a second conventional magnetron sputtering apparatus according to the second prior art.

FIG. 34 shows a cross sectional view of an erosion portion formed on a target when being sputtered by the second conventional magnetron sputtering apparatus shown in FIG. 33.

FIG. 35 is a conceptional cross sectional view of a third conventional magnetron sputtering apparatus according to the third prior art.

FIG. 36 shows a cross sectional view of an erosion portion formed on a target when being sputtered by the third conventional magnetron sputtering apparatus shown in FIG. 35.

### DETAILED DESCRIPTION OF THE PREFERRED EMBODIMENTS

### First Embodiment

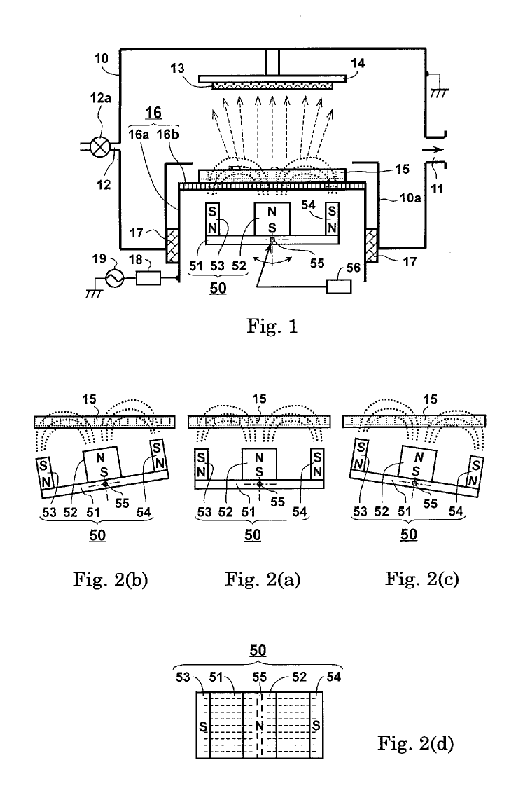

FIG. 1 is a cross sectional view of a magnetron sputtering apparatus according to a first embodiment of the present invention.

FIGS. 2(a) to 2(c) are pattern diagrams showing a relationship between a magnetic field (magnetic flux lines) and a target when swinging a magnetic field generating section of the magnetron sputtering apparatus shown in FIG. 1.

FIG. 2(d) is a plan view of the magnetic field generating section shown in FIGS. 1 and 2(a) to 2(c).

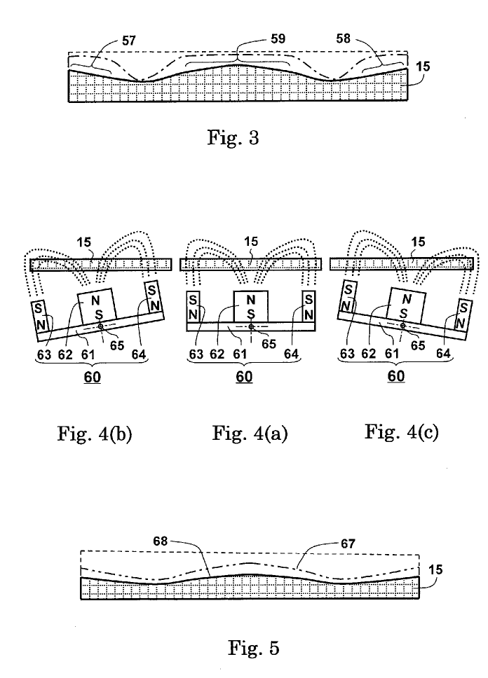

FIG. 3 shows a cross sectional view of an erosion portion formed on a target when being sputtered by the magnetron sputtering apparatus according to the first embodiment of the present invention.

In FIG. 1, a magnetron sputtering apparatus is composed of a vacuum chamber 10, a substrate 13, an anode 14, a target 15, a cathodic body 16 and a magnetic field generating section 50. The vacuum chamber 10 is provided with an exhaust opening 11, which is connected to a not shown vacuum pump, and a gas intake duct 12 for introducing inert gas through a flow control valve 12a.

Inside the vacuum chamber 10, the anode 14 is disposed as a substrate holder to hold the substrate 13 of which surface is formed with a thin film, and the cathodic body 16 on which the target 15 is securely placed is disposed so as to confront with the anode 14.

Further, a high frequency power supply 19 is connected to the cathodic body 16 through an impedance matching device 18, wherein the high frequency power supply 19 and the vacuum chamber 10 is grounded.

The cathodic body 16 is further composed of a cylinder section 16a and a target supporting section 16b and disposed inside a cathode shielding section 10a, which constitutes the vacuum chamber 10, through an insulative member 17.

The magnetic field generating section 50 is provided at a position close to the target 15 inside the cathodic body 16 and generates a magnetic field on a surface of the target 15.

In this first embodiment, the target 15 is a square flat plate, so that the magnetic field generating section 50 is composed of a yoke 51 in flat plate corresponding to the target 15 in square and three permanent magnets 52, 53 and 54 in rectangular parallelepiped. First, second and third permanent magnets 52, 53 and 54 are fixed on the yoke 52 in parallel with each other. The first permanent magnet 52 disposed in the middle of the yoke 51 is magnetized such that a top end surface toward the target supporting section 16b is the N-pole. In case of the second and third permanent magnets 53 and 54 disposed on the both ends of the yoke 51, each top end surface of them toward the target supporting section 16b is magnetized in the S-pole respectively.

The yoke 51 is provided with a hole 55 drilled at the center of a side wall of the yoke 51, so that the magnetic field generating section 50 enables to be supported and pivoted freely by the hole 55. Consequently, the magnetic field generating section 50 enables to be swung to the left and the right within a prescribe angle with centering the hole 55 by means of a driving unit 56 for swinging the magnetic field generating section 50 totally.

As shown in FIGS. 2(a) to 2(d), a magnetic field is configured above the magnetic field generating section 50 by magnetic flux lines between the first permanent magnet 52 disposed in the middle of the yoke 51 and the second and third permanent magnets 53 and 54 disposed on the both ends of the yoke 51.

In case the magnetic field generating section 50 is in neutral state as shown in FIG. 2(a), a magnetic field (magnetic flux lines) is approximately generated in parallel with the surface of the target 15.

In case the magnetic field generating section 50 is swung and slanted to the left as shown in FIG. 2(b), a magnetic field generated between the first permanent magnet 52 and the second permanent magnet 53 moves to the left of the target 15 on the surface and another magnetic field generated between the first permanent magnet 52 and the third permanent magnet 54 moves to the center of the target 15 on the surface.

On the contrary, in case the magnetic field generating section 50 is swung and slanted to the right as shown in FIG. 2(c), the other magnetic field generated between the first permanent magnet 52 and the third permanent magnet 54 moves to the right of the target 15 on the surface and the magnetic field generated between the first permanent magnet 52 and the second permanent magnet 53 moves to the center of the target 15 on the surface.

As mentioned above, a plasma converged area moves on the surface of the target 15 as long as the magnetic field generating section 50 is swung by the driving unit 56 while sputtering.

Accordingly, an erosion area reciprocates right and left on the surface of the target 15.

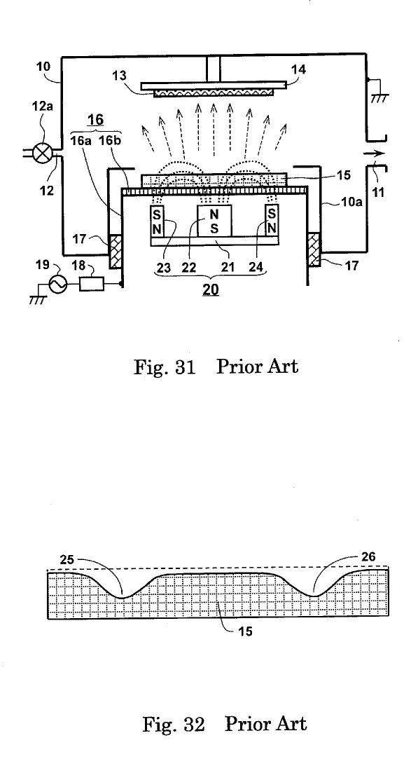

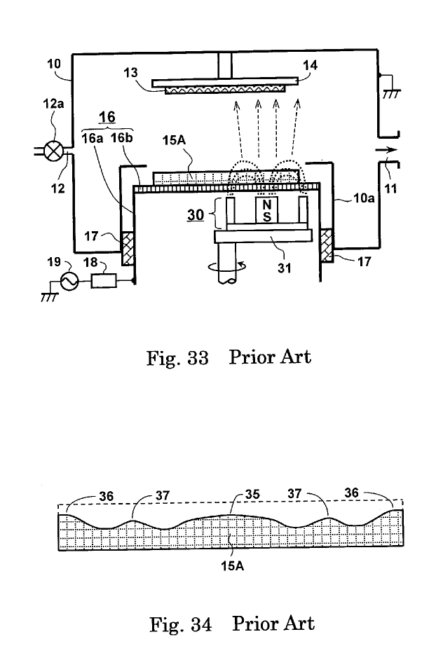

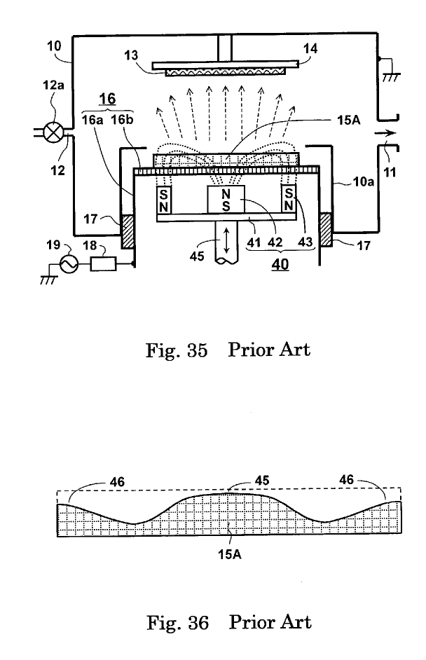

As a result of reciprocating erosion area, an erosion state conducted by the magnetron sputtering apparatus of the first embodiment is exhibited by a block line in FIG. 3. As shown in FIG. 3, erosion is more proceeded at a middle section 59 and circumferential sections 57 and 58, and resulting in obtaining a uniform erosion state across the target 15 in comparison with the erosion state exhibited by a chain line in FIG. 3, which is conducted by the first conventional magnetron sputtering apparatus shown in FIG. 31 under the same processing time period. In addition, a broken line exhibits an original surface of the target 15.

According to the first embodiment of the present invention, the magnetron sputtering apparatus shown in FIG. 1 enables to extremely improve usable efficiency of target as well as improving sputtering efficiency.

In the first embodiment of the present invention, top end surfaces of the first permanent magnet 52 and the second and third permanent magnets 53 and 54, which confront with the target supporting section 16b, are magnetized in the N-pole and the S-pole respectively. However, a plasma converged area is independent from the magnetic polarity, so that the same effect enables to be conducted even by the first to third permanent magnets 52, 53 and 54 of which magnetic polarities are inverted respectively.

### Second Embodiment

A magnetron sputtering apparatus according to a second embodiment is identical to that shown in FIG. 1 according to the first embodiment of the present invention except for the magnetic field generating section 50, so that description is mainly given to operations of a magnetic field generating section.

FIGS. 4(a) to 4(c) are pattern diagrams showing a relationship between a magnetic field (magnetic flux lines) and a target when swinging a magnetic field generating section of the magnetron sputtering apparatus according to the second embodiment of the present invention.

FIG. 5 shows a cross sectional view of an erosion portion formed on a target when being sputtered by the magnetron sputtering apparatus according to the second embodiment of the present invention.

In FIGS. 4(a) to 4(c), a magnetic field generating section 60 is composed of a yoke 61 in flat plate corresponding to the target 15 in square and three permanent magnets 62, 63 and 64 in rectangular parallelepiped. First, second and third permanent magnets 62, 63 and 64 are fixed on the yoke 62 in parallel with each other. The first permanent magnet 62 disposed in the middle of the yoke 61 is magnetized such that a top end surface toward the target supporting section 16b is the N-pole. In case of the second and third permanent magnets 63 and 64 disposed on the both ends of the yoke 61, each top end surface of them toward the target supporting section 16b is magnetized in the S-pole respectively.

The yoke 61 is provided with a hole 65 drilled at the center of a side wall of the yoke 61, so that the magnetic field generating section 60 enables to be supported and pivoted freely by the hole 65. Consequently, the magnetic field generating section 60 enables to be swung to the right and the left within a prescribed angle with centering the hole 65.

Magnetic field strength at the N-pole surface (top end surface) of the first permanent magnet 62 is designated to be disproportionated against magnetic field strength at the S-pole surface (top end surface) of the second or third permanent magnet 63 or 64. Consequently, as shown in FIGS. 4(a) to 4(c), a magnetic field (magnetic flux lines) generated between the first permanent magnet 62 and the second or third permanent magnet 63 or 64 is shifted outward in comparison with the magnetic field shown in FIGS. 2(a) to 2(c) generated by the magnetic field generating section 50 according to the first embodiment of the present invention. More accurately, with defining that a mean value of magnetic field strength at the top end surface of the first permanent magnet 62 is H₂₁, an area of the top end surface of the first permanent magnet 62 is S₂₁, a mean value of each magnetic field strength at the respective top end surfaces of the second and third permanent magnets 63 and 64 is H₂₂, and a summed area of the respective top end surfaces of the second and third permanent magnets 63 and 64 is S₂₂, the first, second and third permanent magnets 62, 63 and 64 are magnetized so as to satisfy a relationship of “H₂₁×S₂₁>H₂₂×S₂₂”.

Accordingly, magnetic flux lines radiated from the top end surface of the first permanent magnet 62 are apt to invade into outside areas of the second and third permanent magnets 63 and 64, and resulting in shifting a magnetic field outward.

When the magnetic field generating section 60 is swung to the left or the right within a prescribed angle with centering the hole 65, the magnetic field generated as mentioned above is formed on the target 15 as shown in FIGS. 4(b) and 4(c).

In this case, one of the second and third permanent magnets 63 and 64 leaves from the target 15 and the other approaches the target 15 alternately when the magnetic field generating section 60 is swung. A magnetic filed generated between the first permanent magnet 62 and either one of the second and third permanent magnets 63 and 64, which departs from the target 15, moves outward extremely.

On the other hand, another magnetic field generated between the first permanent magnet 62 and either one of the second and third permanent magnets 63 and 64, which approaches the target 15, moves inward. A most converged area of plasma also moves outward or inward in accordance with the moving magnetic field.

Consequently, a sputtering process enables to be conducted by making the plasma converged area move to the right and left in the both sides of the target 15 on the surface, and resulting in improving sputtering efficiency and usable efficiency of the target 15 more than the case conducted by the magnetic field generating section 50 according to the first embodiment of the present invention. In FIG. 5, a chain double-dashed line 67 is an eroded surface of the target 15 that is sputtered by the magnetron sputtering apparatus according to the first embodiment, and a solid line 68 is another eroded surface of the target 15 that is sputtered by the magnetic field generating section 60 according to the second embodiment when the target 15 is sputtered for the same time period as the first embodiment. It is apparent from FIG. 5 that the other surface 68 is more eroded than the surface 67, and that erosion sputtered by the magnetic field generating section 60 is uniformly proceeded across the target 15 more than the erosion sputtered by the magnetic field generating section 50 according to the first embodiment.

### Third Embodiment

A magnetron sputtering apparatus according to a third embodiment is identical to that shown in FIG. 1 according to the first embodiment of the present invention except for the target 15, the magnetic field generating section 50 and the driving unit 56, so that the same components are denoted by the same reference signs and details of their functions and operations are omitted and description is mainly given to operations of a magnetic field generating section.

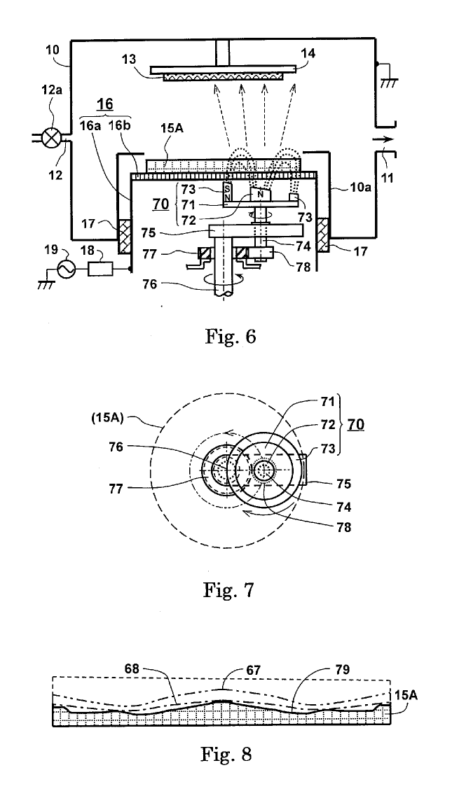

FIG. 6 is a cross sectional view of a magnetron sputtering apparatus according to a third embodiment of the present invention.

FIG. 7 is a plan view of a supporting mechanism and a rotation and revolution mechanism of a magnetic field generating section in the magnetron sputtering apparatus shown in FIG. 6.

FIG. 8 shows a cross sectional view of an erosion portion formed on a target when being sputtered by the magnetron sputtering apparatus according to the third embodiment of the present invention.

In FIG. 6, a target 15A is in disciform. A magnetic field generating section 70 is composed of a yoke 71 in circular shape having a diameter of half a diameter of the target 15A approximately, a first permanent magnet 72 in columnar shape that is disposed and fixed in the middle of the yoke 71 and a second permanent magnet 73 in annular shape that is fixed on the circumferential area of the yoke 71 with surrounding the first permanent magnet 72. The first and second permanent magnets 72 and 73 are magnetized such that a top end surface of the first permanent magnet 72 and a top end surface of the second permanent magnet 73 toward the target supporting section 16b is the N-pole and the S-pole respectively.

Further, with defining that a mean value of magnetic field strength at a top end surface of the first permanent magnet 72 is H₃₁, an area of the top end surface of the first permanent magnet 72 is S₃₁, a mean value of magnetic field strength at a top end surface of the second permanent magnet 73 is H₃₂, and an area of the top end surface of the second permanent magnet 73 is S₃₂, the first permanent magnet 72 and the second permanent magnet 73 is magnetized so as to satisfy a relationship of “H₃₁×S₃₁>H₃₂×S₃₂”.

Furthermore, as shown in FIG. 6, each top surface of the first and second permanent magnets 72 and 73 is slanted such that the first and second permanent magnets 72 and 73 are cut by a virtual inclined plane common to them.

As shown in FIGS. 6 and 7, a first rotary shaft 74 is connected to a center axis of the yoke 71 on the bottom and rotatably supported by a rotary platform 75. The rotary platform 75 is securely supported by a second rotary shaft 76, which is rotatably supported vertically by being approximately disposed at a center axis of the cathodic body 16.

Further, the second rotary shaft 76 is mounted with a planet gear mechanism. The planet gear mechanism is composed of a sun gear 77 and a planet gear 78. The sun gear 77 is fixed to the second rotary shaft 76 with centering a center axis of the second rotary shaft 76. The planet gear 78 that engages with the sun gear 77 is mounted on a bottom end of the first rotary shaft 74, wherein the first rotary shaft 74 passes through the rotary platform 75 so as to be rotatable freely. Consequently, a rotational and orbital mechanism is constituted such that the magnetic field generating section 70 is totally revolved in orbital motion with centering the second rotary shaft 76 while rotating with centering the first rotary shaft 74 by rotating the second rotary shaft 76.

According to the magnetron sputtering apparatus of the third embodiment, as mentioned above, magnetic field strength at the top end surface of the first permanent magnet 72 is deferent from that of the second permanent magnet 73, and each top end surface of the first and second permanent magnets 72 and 73 is formed in a shape that is cut by a virtual inclined plane. Therefore, a magnetic field generated by the magnetic field generating section 70 is shifted outward from the center of the target 15A. A magnetic field generated on the top end surface of the second permanent magnet 73, which is closer to the target 15, is shifted further to the inner side of the magnetic field generating section 70. On the contrary, another magnetic field generated on the top end surface of the second permanent magnet 73, which is away from the target 15, is shifted further to the outer side of the magnetic field generating section 70.

As shown in FIG. 7, when the magnetic field generating section 70 rotates around the first rotary shaft 74 and is revolved in orbital motion by the second rotary shaft 76 that is rotated, the above-mentioned magnetic fields also rotate and are revolved in orbital motion on the surface of the target 15A. Therefore, an erosion area on the surface of the target 15A expands by the rotation of the magnetic field generating section 70 and expands furthermore across the target 15A by the revolution in orbital motion of the magnetic field generating section 70. Consequently, erosion is conducted all over the target 15A uniformly.

In other words, each of magnetic flux lines of a magnetic filed that is generated by the magnetic field generating section 70 moves allover the surface of the target 15A while each of the magnetic flux lines describes a locus of the cycloidal curve, and resulting in forming a plasma converged area allover the surface of the target 15A uniformly.

However, an area through which magnetic flux lines do not pass may happen to be produced in case each of the magnetic flux lines always describes the same locus.

Accordingly, it is desirable for the rotation and revolution mechanism shown in FIGS. 6 and 7 that a ratio of a rotational frequency of the rotation of the magnetic field generating section 70 to a revolution frequency of the orbital motion of the magnetic field generating section 70 should no be integral multiples by appropriately designating each module of the sun gear 77 and the planet gear 78.

An erosion state of the target 15A according to the third embodiment of the present invention is shown in FIG. 8. In FIG. 8, a solid line 79 is an eroded surface of the target 15A that is sputtered by the magnetron sputtering apparatus according to the third embodiment, a chain double-dashed line 67 is the eroded surface of the target 15 shown in FIG. 3 according to the first embodiment and a chain line 68 is the eroded surface of the target 15 shown in FIG. 5 according to the second embodiment. As shown in FIG. 8, the eroded surface 79 is flattened furthermore than the eroded surfaces 67 and 68.

Accordingly, by using the magnetron sputtering apparatus according to the third embodiment, usable efficiency of target enables to be improved more.

In the third embodiment, it is defined that each top end surface of the first and second permanent magnets 72 and 73 is formed in the shape being cut by a virtual inclined plane common to them. However, it is not necessary for them that they must be in the same slanting condition. It shall be understood that the first and second permanent magnets 72 and 73 enable to be in any shape as long as a magnetic field between the first permanent magnet 72 and the second permanent magnet 73 is slanted with respect to the surface of the target 15A.

### Fourth Embodiment

A magnetron sputtering apparatus according to a fourth embodiment is identical to the magnetron sputtering apparatus according to the third embodiment of the present invention except for the magnetic field generating section 70, so that descriptions for the same functions and operations as the third embodiment are omitted and description is mainly given to operations of a magnetic field generating section.

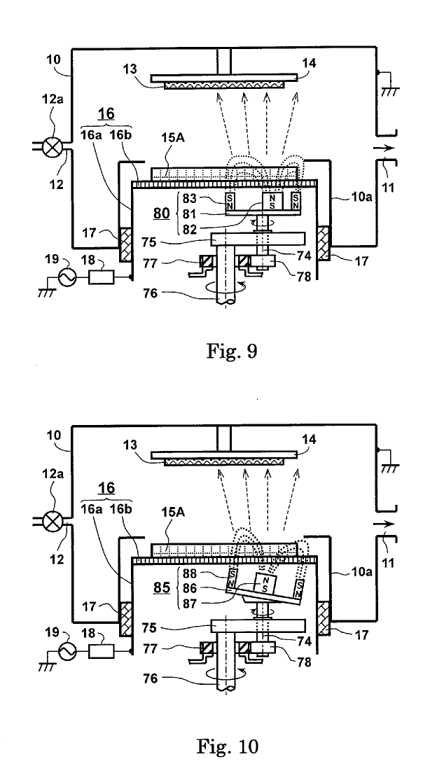

FIG. 9 is a cross sectional view of a magnetron sputtering apparatus according to a fourth embodiment of the present invention.

In FIG. 9, a magnetic field generating section 80 is composed of a yoke 81 in circular shape, a first permanent magnet 82 in columnar shape and a second permanent magnet 83 in annular shape. The magnetic field generating section 80 of the fourth embodiment is different from the magnetic field generating section 70 of the third embodiment in that each height of the first and second permanent magnets 82 and 83 is the same and the first permanent magnet 82 is disposed in an off center position of the yoke 81.

The magnetic field generating section 80 generates a magnetic field on the surface of the target 15A under a disproportionated condition, so that relationship between magnetic field strength and an area with respect to the first and second permanent magnets 82 and 83 is the same as the relationship described in the third embodiment above.

Accordingly, the magnetron sputtering apparatus according to the fourth embodiment enables to realize the same erosion state as that of the third embodiment shown in FIG. 8.

### Fifth Embodiment

A magnetron sputtering apparatus according to a fifth embodiment is identical to the magnetron sputtering apparatus according to the third embodiment of the present invention except for the magnetic field generating section 70, so that descriptions for the same functions and operations as the third embodiment are omitted and description is mainly given to operations of a magnetic field generating section.

FIG. 10 is a cross sectional view of a magnetron sputtering apparatus according to a fifth embodiment of the present invention.

In FIG. 10, a magnetic field generating section 85 is composed of a yoke 86 in circular shape, a first permanent magnet 87 in columnar shape and a second permanent magnet 88 in annular shape. The magnetic field generating section 85 of the fifth embodiment is different from the magnetic field generating section 70 of the third embodiment in that each height of the first and second permanent magnets 87 and 88 is the same.

Further, the magnetic field generating section 85 is fixed to the top end of the first rotary shaft 74 with being slanted off the first rotary shaft 74 by a prescribed angle.

The magnetic field generating section 85 generates a magnetic field on the surface of the target 15A under a disproportionated condition, so that relationship between magnetic field strength and an area with respect to the first and second permanent magnets 87 and 88 is the same as the relationship described in the third embodiment above.

Accordingly, the magnetron sputtering apparatus according to the fifth embodiment enables to realize the same erosion state as that of the third embodiment shown in FIG. 8.

### Sixth Embodiment

A magnetron sputtering apparatus according to a sixth embodiment is identical to the magnetron sputtering apparatus according to the third embodiment of the present invention except for the magnetic field generating section 70, so that descriptions for the same functions and operations as the third embodiment are omitted and description is mainly given to operations of a magnetic field generating section.

FIG. 11 is a cross sectional view of a magnetron sputtering apparatus according to a sixth embodiment of the present invention.

In FIG. 11, a magnetic field generating section 90 is composed of a yoke 91 in circular shape, a first permanent magnet 92 in columnar shape and a second permanent magnet 93 in annular shape. The magnetic field generating section 90 of the sixth embodiment is identical to the magnetic field generating section 85 of the fifth embodiment except for the first permanent magnet 92. In case of the magnetic field generating section 90, the first permanent magnet 92 is disposed in an off center position of the yoke 91.

The magnetic field generating section 90 according to the sixth embodiment generates a magnetic field on the surface of the target 15A under a disproportionated condition, so that relationship between magnetic field strength and an area with respect to the first and second permanent magnets 92 and 93 is the same as the relationship described in the third embodiment above.

Accordingly, the magnetron sputtering apparatus according to the sixth embodiment enables to realize the same erosion state as that of the third embodiment shown in FIG. 8.

### Seventh Embodiment

A magnetron sputtering apparatus according to a seventh embodiment is identical to the magnetron sputtering apparatus shown in FIG. 1 according to the first embodiment of the present invention except for the target 15, the magnetic field generating section 50 and the driving unit 56, so that the same components are denoted by the same reference signs and details of their functions and operations are omitted and description is mainly given to operations of a magnetic field generating section.

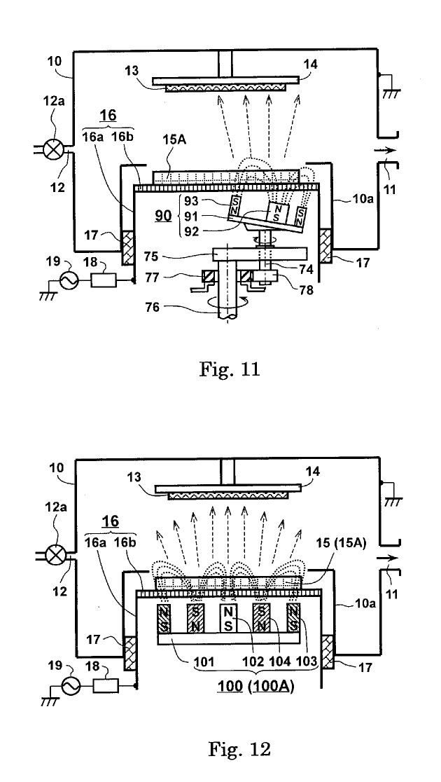

FIG. 12 is a cross sectional view of a magnetron sputtering apparatus according to a seventh embodiment of the present invention.

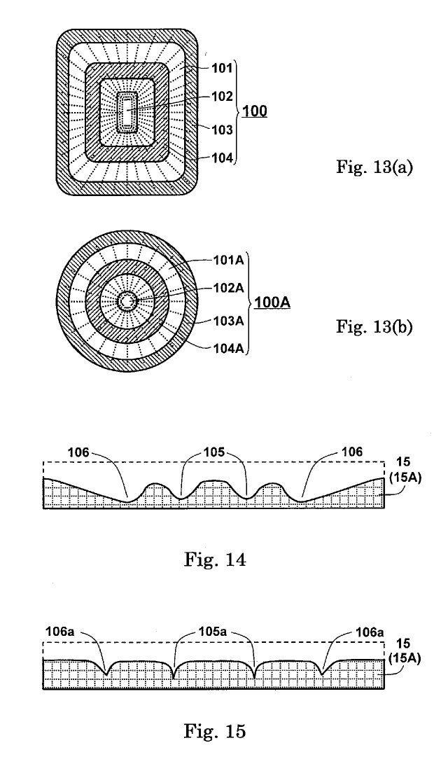

FIG. 13(a) is a plan view of a magnetic field generating section of the magnetron sputtering apparatus shown in FIG. 12 corresponding to a target in square shape.

FIG. 13(b) is a plan view of another magnetic field generating section of the magnetron sputtering apparatus shown in FIG. 12 corresponding to a target in disciform.

FIG. 14 shows a cross sectional view of an erosion portion formed on a target when being sputtered by the magnetron sputtering apparatus shown in FIG. 12.

FIG. 15 shows another cross sectional view of an erosion portion formed on the target when being sputtered by the magnetron sputtering apparatus shown in FIG. 12 in case a magnetic field between permanent magnets of the magnetic field generating section is not disproportionated.

In FIG. 12, a magnetic field generating section 100 (100A) is formed in response to a shape of the target 15 (15A). In case the target 15 is in flat square shape, the magnetic field generating section 100 is constituted as shown in FIG. 13(a). In case the target 15A is in flat circular shape, the magnetic field generating section 100A is constituted as shown in FIG. 13(b).

As shown in FIGS. 12 and 13(a), the magnetic field generating section 100 is composed of a yoke 101 in flat square shape having a shape and size corresponding to the target 15 in flat square shape, a first permanent magnet 102 in columnar shape disposed in a center region of the yoke 101, a second permanent magnet 103 in annular shape disposed in a circumferential area of the yoke 101 and a third permanent magnet 104 in annular shape disposed between the first permanent magnet 102 and the second permanent magnet 103.

On the other hand, as shown in FIGS. 12 and 13(b), the magnetic field generating section 100A is composed of a yoke 101A in flat circular shape having a shape and size corresponding to the target 15A in disciform, a first permanent magnet 102A in columnar shape disposed in the middle of the yoke 101A, a second permanent magnet 103A disposed in a circumferential area of the yoke 101A and a third permanent magnet 104A disposed between the first permanent magnet 102A and the second permanent magnet 103A.

In the third permanent magnet 104 (104A), a top end surface toward the target supporting section 16b is inversely magnetized with respect to top end surfaces of the first permanent magnet 102 (102A) and the second permanent magnet 103 (103A). In this seventh embodiment, as shown in FIG. 12, each top end surface of the first and second permanent magnets 102 (102A) and 103 (103A) are magnetized in the N-pole. On the contrary, a top end surface of the third permanent magnet 104 (104A) is magnetized in the S-pole.

Further, with defining that a mean value of magnetic field strength at the top end surface of the third permanent magnet 104 (104A) is H₄₁, an area of the top end surface of the third permanent magnet 104 (104A) is S₄₁, a mean value of each magnetic field strength at the respective top end surfaces of the first and second permanent magnets 102 (102A) and 103 (103A) is H₄₂, and a summed area of the top end surfaces of the first and second permanent magnets 102 (102A) and 103 (103A) is S₄₂, the first, second and third permanent magnets 102 (102A), 103 (103A) and 104 (104A) are magnetized so as to satisfy a relationship of “H₄₁×S₄₁>H₄₂×S₄₂”.

Consequently, as shown in FIGS. 12 to 13(b), a first magnetic field is generated between the first permanent magnet 102 (102A) and the third permanent magnet 104 (104A), and a second magnetic field is generated between the second permanent magnet 103 (103A) and the third permanent magnet 104 (104A) respectively. On the surface of the target 15 (15A), a magnetic field is generated in two annular areas. However, as shown in FIG. 12, the first magnetic field between the first permanent magnet 102 (102A) and the third permanent magnet 104 (104A) is shifted toward the center of the first permanent magnet 102 (102A) due to the above-mentioned relationship of magnetic field strength. On the contrary, the second magnetic field between the second permanent magnet 103 (103A) and the third permanent magnet 104 (104A) is shifted toward the outer circumferential area of the magnetic field generating section 100 (100A).

Further, the first, second and third permanent magnets 102 (102A), 103 (103A) and 104 (104A) are disposed closely with respect to each other. Therefore, the first and second magnetic fields, which are formed in the target 15 (15A), appropriately describe a closed loop although an area of the target 15 (15A) is relatively large, and resulting in constituting duplicate plasma converged areas in which magnetron discharge is enabled.

Accordingly, strong erosion occurs in a wide area of duplicated annular magnetic fields, which are formed on the surface of the target 15 (15A). An erosion state of the target 15 (15A) is shown in FIG. 14. In FIG. 14, recessed portions 105 and 106 are most eroded portions in the duplicated annular magnetic fields. As shown in FIG. 14, the surface of the target 15 (15A) is extremely rugged in comparison with the other embodiments. However, erosion is averaged totally, and resulting in enabling to improve sputtering efficiency and usable efficiency of target because distance between each top end surface of the first, second and third permanent magnets 102 (102A), 103 (103A) and 104 (104A) and the surface of the target 15 (15A) becomes smaller in accordance with the target 15 (15A) being eroded, and then the duplicated plasma converged areas gradually move.

In this connection, since a location of a most converged area of plasma is fixed regardless of distance between a top end surface of each permanent magnet and the top surface of the target 15 (15A), an erosion area hardly moves in case magnetic field strength of the permanent magnets of the magnetic field generating section 100 (100A) is not designated to be the above-mentioned disproportionated relationship among them. Consequently, the target 15 (15A) is partially eroded as shown in FIG. 15.

In other words, erosion develops only in an annular area, and resulting in forming narrow grooves 105a and 106a. Consequently, sputtering efficiency and usable efficiency of target is extremely deteriorated.

### Eighth Embodiment

A magnetron sputtering apparatus according to a eighth embodiment is identical to that shown in FIG. 12 according to the seventh embodiment of the present invention except for that the magnetic field generating section 100 (100A) enables to be moved vertically, so that the same components are denoted by the same reference signs and details of their functions and operations are omitted and description is mainly given to operations of a magnetic field generating section. In this eighth embodiment, particularly in FIGS. 17(a) and 17(b), reference signs of each component of the magnetic field generating section and the target are generically numbered as they are in square shape as shown in FIG. 13(a).

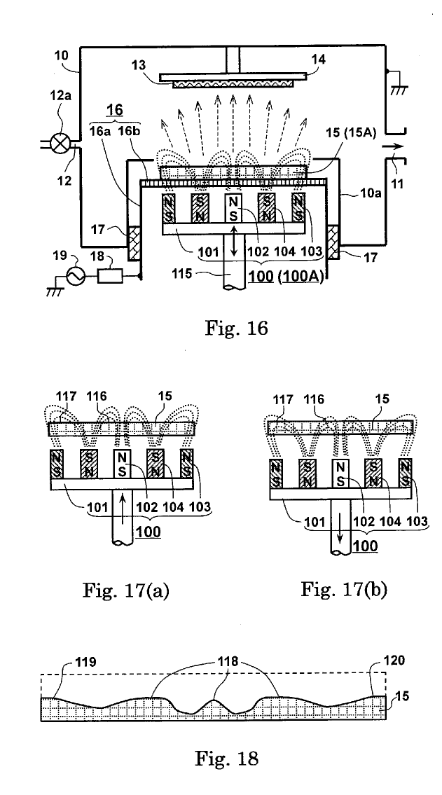

FIG. 16 is a cross sectional view of a magnetron sputtering apparatus according to an eighth embodiment of the present invention.

FIGS. 17(a) and 17(b) are pattern diagrams showing a relationship between a magnetic field (magnetic flux lines) and a target when a magnetic field generating section of the magnetron sputtering apparatus shown in FIG. 16 is moved vertically.

FIG. 18 shows a cross sectional view of an erosion portion formed on a target when being sputtered by the magnetron sputtering apparatus shown in FIG. 16.

As shown in FIG. 16, the magnetic field generating section 100 is moved vertically by a shaft 115 that is fixed to the center of the yoke 101 on the bottom.

In FIGS. 17(a) and 17(b), annular areas 116 and 117 move horizontally in accordance with the vertical movement of the magnetic field generating section 100, wherein the annular areas are caused by the first and second magnetic fields that are generated between the first and third permanent magnets 102 and 104 and between the second and third permanent magnets 103 and 104 respectively and constitute a plasma converged area on the surface of the target 15.

As mentioned in the seventh embodiment above, the first magnetic field generated between the first permanent magnet 102 and the third permanent magnet 104 is shifted toward the center of the first permanent magnet 102 and the second magnetic field generated between the second permanent magnet 103 and the third permanent magnet 104 is shifted toward the outer circumferential area of the magnetic field generating section 100. Therefore, the annular area 116 moves outward and the other annular area 117 moves inward, when the magnetic field generatign section 100 is moved upward as shown in FIG. 17(a). On the contrary, when the magnetic field generating section 100 is moved downward as shown in FIG. 17(b), the annular area 116 and the other annular area 117 moves inward and outward respectively.

Consequently, an erosion area on the surface of the target 15 is expanded by the movement of the annular areas 116 and 117 in response to the vertical movement of the magnetic field generating section 100, and finally resulting in obtaining an erosion state shown in FIG. 18. In FIG. 18 as compared to FIG. 14, erosion is developed in raised portions 118 more than that equivalent to in FIG. 14 although the surface of the target 15 is still ragged.

Further, erosion is also developed in outer circumferential areas 119 and 120 more than that equivalent to in FIG. 14, so that a flatter surface enables to be obtained.

Accordingly, it is understood that sputtering efficiency and usable efficiency of target is improved furthermore.

### Ninth Embodiment

A magnetron sputtering apparatus according to a ninth embodiment is identical to that shown in FIG. 1 according to the first embodiment of the present invention except for the magnetic field generating section 50 and the driving unit 56, so that the same components are denoted by the same reference signs and details of their functions and operations are omitted and description is mainly given to operations of a magnetic field generating section.

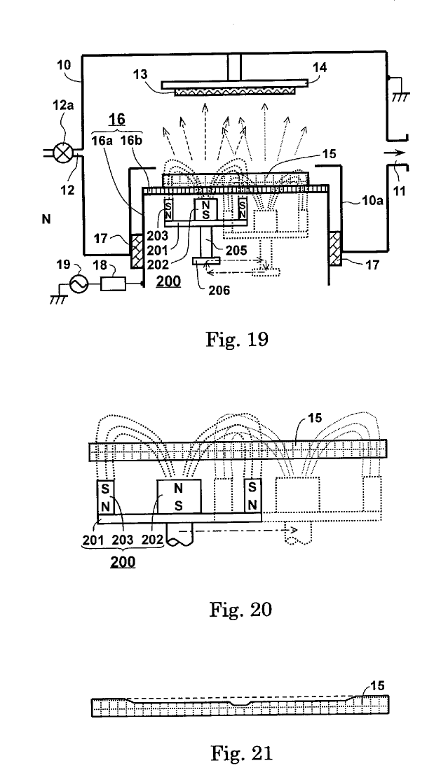

FIG. 19 is a cross sectional view of a magnetron sputtering apparatus according to a ninth embodiment of the present invention.

FIG. 20 is a pattern diagram showing a relationship between a magnetic field (magnetic flux lines) and a target when a magnetic field generating section of the magnetron sputtering apparatus shown in FIG. 19 is moved horizontally while the magnetic field generating section is disposed in close proximity to the target.

FIG. 21 shows a cross sectional view of an erosion portion formed on the target when the magnetic field generating section is moved horizontally as shown in FIG. 20 while the magnetic field generating section is disposed in close proximity to the target.

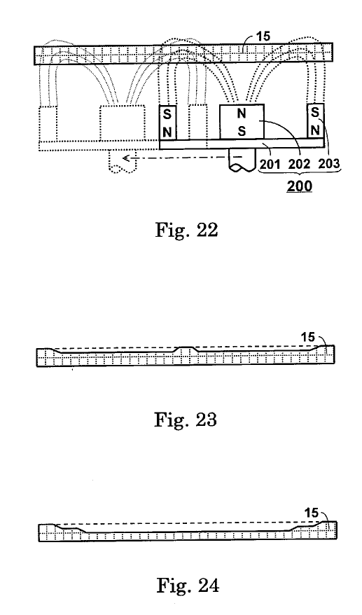

FIG. 22 is a pattern diagram showing a relationship between a magnetic field (magnetic flux lines) and the target when the magnetic field generating section of the magnetron sputtering apparatus shown in FIG. 19 is moved horizontally while the magnetic field generating section is disposed apart from the target.

FIG. 23 shows a cross sectional view of an erosion portion formed on the target when the magnetic field generating section is moved horizontally as shown in FIG. 22 while the magnetic field generating section is disposed apart from the target.

FIG. 24 shows a cross sectional view of an erosion portion formed on the target when the magnetic field generating section is moved vertically and horizontally as shown in FIGS. 20 and 22 with respect to the target.

In FIGS. 19, 20 and 22, a magnetic field generating section 200 is composed of a yoke 201, a first yoke-type permanent magnet (hereinafter referred to as first permanent magnet) 202, which is disposed and fixed in the middle of the yoke 201, and a second yoke-type permanent magnet (hereinafter referred to as second permanent magnet) 203, which is disposed and fixed in a circumferential area of the yoke 201 with surrounding the first permanent magnet 202, wherein a height of the second permanent magnet 203 is the same as that of the first permanent magnet 202. A top end surface of the first permanent magnet 202 is magnetized in the N-pole. On the contrary, a top end surface of the second permanent magnet 203 is magnetized in the S-pole. Magnetic field strength of the top end surface of the second permanent magnet 203 is designated to be weaker than that of the first permanent magnet 202.

Further, the magnetic field generating section 200 is linked to a motion controller unit 206 through a shaft 205. The motion controller unit 206 drives the magnetic field generating section 200 to move vertically and horizontally. More accurately, the motion controller unit 206 moves the magnetic field generating section 200 upward first, to the right, downward and finally to the left reciprocally.

As mentioned above, the magnetic field strength of the top end surface of the first permanent magnet 202 is stronger than that of the second permanent magnet 203, so that a magnetic field (magnetic flux lines) that is generated from the first permanent magnet 202 to the second permanent magnet 203 is shifted outward.

When the motion controller unit 206 makes the magnetic field generating section 200 move horizontally within reach of the magnetic field generated between the first and second permanent magnets 202 and 203 to the target 15, the magnetic field moves horizontally. Consequently, an erosion area to be appeared on the surface of the target 15 enables to be expanded horizontally.

Further, when the magnetic field generating section 200 is moved downward, the magnetic field, which is generated between the first permanent magnet 202 and the second permanent magnet 203 and shifted outward, moves outward furthermore on the surface of the target 15. Consequently, the vertical movement of the magnetic field generating section 200 enables to expand an erosion area wider in conjunction with expansion of an erosion area caused by the horizontal movement of the magnetic field generating section 200.

With referring to FIGS. 20 to 24, development of an erosion area is depicted next.

As shown in FIG. 20, when the magnetic field generating section 200 is lifted to an uppermost position close to the target 15 and moved horizontally to the right, the magnetic field generated between the first and second permanent magnets 202 and 203 overlaps in the middle of the target 15, so that the middle portion of the target 15 is sputtered for a longer time period than other area. Consequently, as shown in FIG. 21, an eroded potion is made deeper in the middle of the target 15. On the other hand, the circumferential area of the target 15 is not sputtered or not eroded.

As shown in FIG. 22, when the magnetic field generating section 200 is lowered to a lowermost position away from the target 15 and moved horizontally to the left, the magnetic field disables to reach to the middle of the target 15, so that the middle portion of the target 15 is hardly sputtered. Consequently, as shown in FIG. 23, the middle portion of the target 15 is not eroded.

In this connection, when the magnetic field generating section 200 is moved vertically and horizontally in a sequential motion, the target 15 is resulted in being eroded as shown in FIG. 24 in total. The erosion state shown in FIG. 24 is a combination of FIG. 21 and FIG. 23 as a result.

Accordingly, an erosion area in uniform depth enables to be formed over the surface of the target 15 except for the outer circumferential area.

As mentioned above, according to the ninth embodiment of the present invention, the magnetron sputtering apparatus is provided with the magnetic filed generating section 200, which is composed of the first permanent magnet 202 having stronger magnetic field strength and the second permanent magnet 203 having weaker magnetic field strength, and the motion controller unit 206 so as to move the magnetic field generating section 200 vertically and horizontally within reach of the magnetic field generated between the first and second permanent magnets 202 and 203 to the target 15.

Accordingly, by moving the magnetic field generating section 200 vertically and horizontally in a sequential motion, an erosion area enables to be expanded, and resulting in enabling to improve sputtering efficiency and usable efficiency of target.

### Tenth Embodiment

A magnetron sputtering apparatus according to a tenth embodiment is identical to that shown in FIG. 19 according to the ninth embodiment of the present invention except for the motion controller unit 206, so that the same components are denoted by the same reference signs and details of their functions and operations are omitted and description is mainly given to operations of a magnetic field generating section.

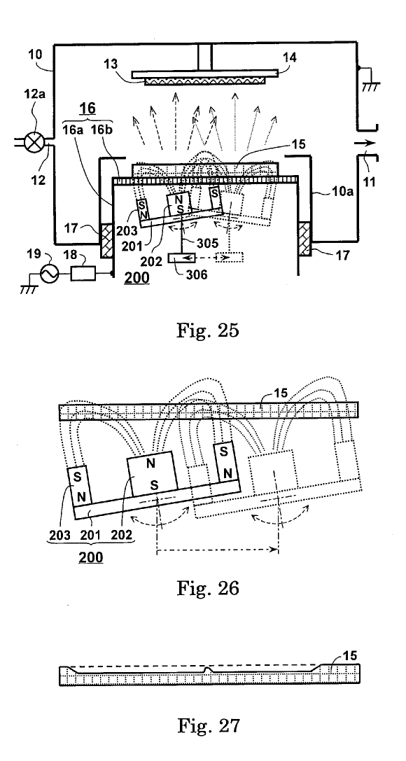

FIG. 25 is a cross sectional view of a magnetron sputtering apparatus according to a tenth embodiment of the present invention.

FIG. 26 is a pattern diagram showing a relationship between a magnetic field (magnetic flux lines) and a target when a magnetic field generating section of the magnetron sputtering apparatus shown in FIG. 25 is moved horizontally while the magnetic field generating section is slanted to the left by a prescribed angle.

FIG. 27 shows a cross sectional view of an erosion portion formed on the target when the magnetic field generating section is moved horizontally while the magnetic field generating section is slanted as shown in FIG. 26.

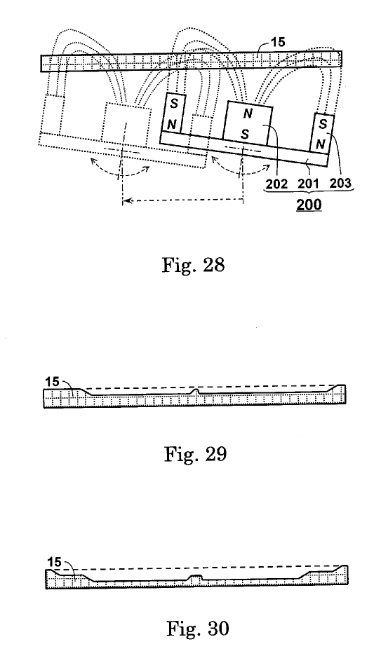

FIG. 28 is a pattern diagram showing a relationship between a magnetic field (magnetic flux lines) and a target when the magnetic field generating section of the magnetron sputtering apparatus shown in FIG. 25 is moved horizontally while the magnetic field generating section is slanted to the right by a prescribed angle.

FIG. 29 shows a cross sectional view of an erosion portion formed on the target when the magnetic field generating section is moved horizontally while the magnetic field generating section is slanted as shown in FIG. 28.

FIG. 30 shows a cross sectional view of an erosion portion formed on the target when the magnetic field generating section is moved horizontally while the magnetic field generating section is slanted to the left and the right as shown in FIGS. 26 and 28.

As shown in FIG. 25, a magnetron sputtering apparatus according to the tenth embodiment is provided with a slanting motion controller unit 306, which drives the magnetic field generating section 200 to swing within a prescribed angle and also to move horizontally through a link 305.

With referring to FIGS. 26 to 30, development of an erosion area is depicted next.

As shown in FIG. 26, when the magnetic field generating section 200 is slanted counterclockwise by the prescribed angle, a magnetic field in the left side of the magnetic field generating section 200 (hereinafter referred to as left magnetic field) is substantially the same condition as the magnetic field shown in FIG. 22, that is, the magnetic field generating section 200 is apart form the target 15. Consequently, the left magnetic field is shifted outward, further to the left.

On the contrary, in the right side of the magnetic field generating section 200, a magnetic field in the right (hereinafter referred to as right magnetic field) is substantially the same condition as the magnetic field shown in FIG. 20, that is, the magnetic field generating section 200 approaches the target 15. Consequently, the right magnetic field is shifted toward the middle of the magnetic field generating section 200. In this connection, when the magnetic field generating section 200 is moved horizontally to the right while the magnetic field generating section 200 is slanted counterclockwise by the prescribed angle as shown in FIG. 26, a left part of the target 15 is sputtered, However, a right end portion of the target 15 is not sputtered sufficiently. Consequently, the target 15 is eroded as shown in FIG. 27.

Further, as shown in FIG. 28, the magnetic field generating section 200 is slanted clockwise within the prescribed angle and moved horizontally to the left, the magnetic field generated between the first and second permanent magnets 202 and 203 is arranged in reverse to that shown in FIG. 26 mentioned above, so that the target 15 is eroded as shown in FIG. 29 that is symmetrical to FIG. 27.

In this connection, when the magnetic field generating section 200 is moved horizontally while the magnetic field generating section 200 is slanted to the left and right within the prescribed angle as shown in FIGS. 26 and 28 sequentially, the target 15 is resulted in being eroded as shown in FIG. 30 in total. The erosion state shown in FIG. 30 is average of the erosion states shown in FIGS. 27 and 29. Consequently, an erosion area in uniform depth enables to be formed over the surface of the target 15 except for the middle and the outer circumferential area of the target 15.

Accordingly, by swinging the magnetic field generating section 200 and by moving the magnetic field generating section 200 horizontally in a sequential motion, an erosion area enables to be expanded, and resulting in enabling to improve sputtering efficiency and usable efficiency of target.

As mentioned above, according to the present invention, there provided a magnetron sputtering apparatus, which enables to develop erosion uniformly on a surface of a target, and resulting in improving useable efficiency of target as well as sputtering efficiency.

While the invention has been described above with reference to a specific embodiment thereof, it is apparent that many changes, modifications and variations in configuration, materials and the arrangement of equipment and devices can be made without departing form the invention concept disclosed herein.

Further, it will be apparent to those skilled in the art that various modifications and variations could be made in the magnetron sputtering apparatus field in the present invention without departing from the scope of the invention.

1. A magnetron sputtering apparatus comprising:
a vacuum chamber;
a target;
a substrate;
an anode for supporting the substrate disposed in the vacuum chamber;
a cathodic body for supporting the target allocated so as to confront with the anode; and
a magnetic field generating section for generating a magnetic field on a surface of the target, being allocated in neighborhood of one side of the cathodic body opposite to the target,
wherein the target is in a shape of square flat plate, and
wherein the magnetic field generating section is further composed of a yoke in flat plate corresponding to the target, a first permanent magnet in rectangular parallelepiped being disposed in the middle of the yoke and second and third permanent magnets in rectangular parallelepiped being disposed in both end portions of the yoke respectively,
the magnetron sputtering apparatus further comprising a driving means for swinging the magnetic field generating section within a prescribed angle with centering a line as an axis of rotation, wherein the line passes through an approximate center of the yoke and is perpendicular to magnetic flux lines of the magnetic field and in parallel with the target.

2. The magnetron sputtering apparatus in accordance with claim 1, wherein the first, second and third permanent magnets of the magnetic field generating section are designated such that a product of a mean value of magnetic field strength at and an area of a top end surface of the first permanent magnet is larger that another product of a mean value of each magnetic field strength at and a sum of each area of top end surfaces of the second and third permanent magnets.

3. A magnetron sputtering apparatus comprising:
a vacuum chamber;
a target;
a substrate;
an anode for supporting the substrate disposed in the vacuum chamber;
a cathodic body for supporting the target allocated so as to confront with the anode; and
a magnetic field generating section for generating a magnetic field on a surface of the target, being allocated in neighborhood of one side of the cathodic body opposite to the target,
wherein the target is in a shape of circular flat plate, and
wherein the magnetic field generating section is further composed of a yoke in circular flat plate having a smaller diameter than the target, a first permanent magnet being disposed in a middle of the yoke and a second permanent magnet in annular shape being disposed in a circumferential area of the target, and
wherein the first and second permanent magnets of the magnetic field generating section are designated such that a product of a mean value of magnetic field strength at and an area of a top end surface of the first permanent magnet is larger that another product of a mean value of magnetic field strength at and an area of a top end surface of the second permanent magnet,
the magnetron sputtering apparatus further comprising a rotational driving means for revolving the magnetic field generating section in orbital motion with maintaining a distance from the target constant while rotating the magnetic field generating section.

4. The magnetron sputtering apparatus in accordance with claim 3, wherein top surfaces of the first and second permanent magnets of the magnetic field generating section are slanted in a same direction with respect to the surface of the target.

5. The magnetron sputtering apparatus in accordance with claim 3, wherein the first permanent magnet is disposed in an off center position of the yoke.

6. The magnetron sputtering apparatus in accordance with claim 3, wherein the magnetic field generating section is mounted at a slant with respect to an axis of rotation of the magnetic field generating section

7. The magnetron sputtering apparatus in accordance with claim 3, wherein the magnetic field generating section is mounted at a slant with respect to an axis of rotation of the magnetic field generating section and the first permanent magnet is disposed in an off center position of the yoke.

8. A magnetron sputtering apparatus comprising:
a vacuum chamber;
a target;
a substrate;
an anode for supporting the substrate disposed in the vacuum chamber;
a cathodic body for supporting the target allocated so as to confront with the anode; and
a magnetic field generating section for generating a magnetic field on a surface of the target, being allocated in neighborhood of one side of the cathodic body opposite to the target,
wherein the magnetic field generating section is further composed of a yoke in flat plate corresponding to the target, a first permanent magnet being disposed in the middle of the yoke, a second permanent magnet in annular shape having the same magnetic polarity being disposed in an outer circumferential area of the yoke and a third permanent magnet in annular shape having an inverse magnetic polarity to the first and second permanent magnets being disposed between the first and second permanent magnets, and
wherein the first and second permanent magnets of the magnetic field generating section are designated such that a product of a mean value of magnetic field strength at and an area of a top end surface of the third permanent magnet is larger that another product of a mean value of each magnetic field strength at and a sum of each area of top end surfaces of the first and second permanent magnet.

9. The magnetron sputtering apparatus in accordance with claim 8, further comprising a moving means for moving the magnetic field generating section so as to enable to change a distance between the target and the magnetic field generating section.

10. A magnetron sputtering apparatus comprising:
a vacuum chamber;
a target;
a substrate;
an anode for supporting the substrate disposed in the vacuum chamber;
a cathodic body for supporting the target allocated so as to confront with the anode; and
a magnetic field generating section for generating a magnetic field on a surface of the target, being allocated in neighborhood of one side of the cathodic body opposite to the target,
wherein the magnetic field generating section is further composed of a yoke in flat plate corresponding to the target, a first permanent magnet being disposed in the middle of the yoke and a second permanent magnet having an inverse magnetic polarity to the first permanent magnet and magnetic field strength weaker than the first permanent magnet being disposed in an end portion of the yoke with surrounding the first permanent magnet,
the magnetron sputtering apparatus further comprising a motion controller unit for moving the magnetic field generating section horizontally and vertically within reach of the magnetic field generated between the first and second permanent magnets to the target.

11. A magnetron sputtering apparatus comprising:
a vacuum chamber;
a target;
a substrate;
an anode for supporting the substrate disposed in the vacuum chamber;
a cathodic body for supporting the target allocated so as to confront with the anode; and
a magnetic field generating section for generating a magnetic field on a surface of the target, being allocated in neighborhood of one side of the cathodic body opposite to the target,
wherein the magnetic field generating section is further composed of a yoke in flat plate corresponding to the target, a first permanent magnet being disposed in the middle of the yoke and a second permanent magnet having an inverse magnetic polarity to the first permanent magnet and magnetic field strength weaker than the first permanent magnet being disposed in an end portion of the yoke with surrounding the first permanent magnet,
the magnetron sputtering apparatus further comprising a slanting motion controller unit for swinging the magnetic field generating section within a prescribed angle while pivoting an approximate center of the magnetic field generating section within reach of the magnetic field generated between the first and second permanent magnets to the target.
